(19) United States
(12) Patent Application Publication
(10) Pub. No.: US 2025/0317115 A1
(43) Pub. Date: Oct. 9, 2025

(54) DIRECTED SELF-ASSEMBLY OF HELICES VIA ELECTRODEPOSITION ON END-TETHERED NANOMEMBRANE RIBBONS FOR MILLIMETER-WAVE TRAVELING-WAVE TUBE AMPLIFIERS

(71) Applicants: WISCONSIN ALUMNI RESEARCH FOUNDATION, Madison, WI (US); UNM RAINFOREST INNOVATIONS, Albuquerque, NM (US)

(72) Inventors: Max G. LAGALLY, Madison, WI (US); Anjali CHAUDHARY, Madison, WI (US); Daniel Warren VAN DER WEIDE, Madison, WI (US); Francesca CAVALLO, Albuquerque, NM (US); Divya Jyoti PRAKASH, Albuquerque, NM (US)

(73) Assignees: UNM RAINFOREST INNOVATIONS, Albuquerque, NM (US); WISCONSIN ALUMNI RESEARCH FOUNDATION, Madison, WI (US)

(21) Appl. No.: 18/865,722

(22) PCT Filed: May 15, 2023
(86) PCT No.: PCT/US2023/022211

§ 371 Date: Nov. 14, 2024

Related U.S. Application Data
(60) Provisional application No. 63/342,383, filed on May 16, 2022.

(51) Int. Cl. H03F 3/58; C25D 3/48; C25D 5/18; H01J 23/16; H01J 23/27; H01J 25/34

(52) U.S. Cl. CPC H03F 3/58; C25D 3/48; C25D 5/18; H01J 23/165; H01J 23/27; H01J 25/34

(57) ABSTRACT

Electroplated helical conductors and methods for making the electroplated helical conductors are provided. The electroplated helical conductors are made from pre-formed thermally and electrically conducting nanomembrane ribbons having non-helical or helical configurations. The dimensions and shapes of the pre-formed nanomembrane ribbons are altered and controlled by the electrodeposition of a metal film onto the surfaces of the nanomembrane ribbons.

### CROSS-REFERENCE TO RELATED APPLICATIONS

This application is a U.S. National Phase application of PCT/US2023/022211, filed May 15, 2023, which claims the benefit of U.S. Provisional Patent Application No. 63/342,383, filed on May 16, 2022, the disclosures of which are incorporated by reference herein in their entireties.

### REFERENCE TO GOVERNMENT RIGHTS

This invention was made with government support under FA9550-19-1-0086 awarded by the USAF/AFOSR. The government has certain rights in the invention.

### BACKGROUND

A traveling-wave tube amplifier (TWTA) is a vacuum electronic device enabling interaction between an energetic beam of electrons and an electromagnetic (EM) wave to transfer energy from the electron beam to the EM wave for amplification. TWTAs are used as compact, high-gain, high-power sources of high-frequency radiation in applications such as wireless communications, biomedical imaging, radar, and electronic warfare. Central to the amplification process is a slow-wave structure (SWS) that matches the phase velocity of the EM wave to that of the electron beam; this structure is some form of meander transmission line or, more commonly, a conductive helix. The slow-wave structure conducts the traveling EM wave along a pathway whose total length is greater than the axial dimension along which the electron beam travels; thus, the component of the EM wave velocity along the axial dimension matches that of the electron beam.

Conventional TWTAs use a wire helix whose dimensions are limited by the smallest gauge wire available, the ability to wind the helix with precision, the ability to support the helix to keep it aligned with the electron beam, and the ability to handle and assemble the helix into the structure. Other methods for manufacturing helical SWSs rely on high-precision laser manufacturing and wafer bonding. Unfortunately, these methods are not easily scalable to micro-scale dimensions (and thus millimeter to sub-millimeter frequencies) and do not enable batch fabrication of helical SWSs on inexpensive and large-area substrates.

### SUMMARY

Methods of making helical mechanically stable conductors from electrically and thermally conducting nanomembrane (NM) ribbons via electroplating-induced self-assembly are provided.

One example of a method of making a helical conductor includes the steps of: forming an end-tethered NM ribbon having a first surface, a second surface opposite the first surface, and a thickness of less than 1000 nm, wherein the end-tethered NM ribbon has a non-helical configuration or is a starting helix having a helix diameter and helix pitch; and converting the end-tethered NM ribbon into a final helix by electroplating a metal film having a thickness in the range from 0.2 μm to 10 μm preferentially on the first surface, wherein the electroplating induces the self-assembly of the NM ribbon having the non-helical configuration into the final helix or induces a change in the helix diameter, helix pitch, or both of the starting helix to form the final helix.

Another example of a method of making a helical conductor includes the steps of: forming an end-tethered NM ribbon having a first surface, a second surface opposite the first surface, and a thickness of less than 1000 nm, wherein the end-tethered NM ribbon has a non-helical configuration; and converting the end-tethered NM ribbon into a helix by electroplating a metal film having a thickness in the range from 0.2 μm to 10 μm onto the end-tethered NM ribbon, wherein the electroplating induces the self-assembly of the NM ribbon having the non-helical configuration into a helix

### BRIEF DESCRIPTION OF THE DRAWINGS

Illustrative embodiments of the invention will hereafter be described with reference to the accompanying drawings, wherein like numerals denote like elements.

FIG. 1. Schematic diagram of a method for the fabrication of a helical and a non-helical conductor.

FIG. 2. Schematic diagram of one embodiment of a TWTA.

FIG. 3. Schematic illustration of the role of metal film thickness and stress gradient on the rolling direction of a plated NM ribbon.

FIG. 4. Scanning electron microsope (SEM) images of the outer (panels (a), (d), (g), and (j)), inner (panels (b), (e), (h), and (k)), and cross-sectional (panels (c), (f), (i), and (l)) surfaces of helical NM ribbons after pulse plating using different frequencies, as described in the Example.

FIGS. 5A and 5B. SEM images of a released, end-tethered Cr/Au/Cr NM ribbon having a non-helical configuration before gold electrodeposition (FIG. 5A) and a helical configuration after gold electrodeposition (FIG. 5B).

FIGS. 6A-6D. SEM image of an initial Cr/Au/Cr NM ribbon having a helical configuration (FIG. 6A) before gold electrodeposition. SEM image of the NM ribbon of FIG. 6A after gold electrodeposition, showing an increase in the helix diameter (FIG. 6B). SEM image of another initial Cr/Au/Cr NM ribbon having a helical configuration (FIG. 6C) before gold electrodeposition. SEM image of the NM ribbon of FIG. 6C after gold electrodeposition, showing a decrease in the helix diameter (FIG. 6D). FIGS. 6A-6D illustrate the use of gold electroplating to alter the inner diameter and pitch of a helical NM ribbon.

FIGS. 7A and 7B. Helix diameter (FIG. 7A) before and after electroplating with gold, showing that at a lower thickness of Au electrodeposition (less than approximately 1.6 μm), the additional residual stress in the electroplated film appears to dominate, resulting in a decrease of the diameter of the helix, while at a higher thickness of Au electrodeposition (greater than approximately 1.7 μm), the thickness effects appear to dominate, resulting in an increase of the diameter of the helix. The estimated residual stress in the electrodeposited Au film is shown in FIG. 7B.

### DETAILED DESCRIPTION

Methods of making helical mechanically stable conductors from electrically and thermally conducting NM ribbons via electroplating-induced self-assembly are provided. The helical conductors can be used as SWSs for TWTAs and other applications.

Building on previous work by the inventors in which conductive helices were produced using stress release-induced self-assembly of metal NM ribbon into helical coils, followed by electroplating, this application disclosure describes: (i) the use of electroplating to induce helix self-assembly from a non-helical NM ribbon; and (ii) the use of electroplating to tailor the dimensions of a pre-formed helical NM ribbon.

The methods described herein provide a scalable, wafer-level fabrication process to control the shape and dimensions of a NM ribbon based on the processing parameters used during the electrodeposition of a uniform layer of metal on a stressed or unstressed end-tethered NM ribbon. The helical conductors made using the methods have high electrical and thermal conductance and are stable against mechanical perturbations. Gold (Au) is one example of a metal that can be electrodeposited onto a NM ribbon. However, other electrodepositable metals and metal alloys can be used. These include, but are not limited to, aluminum (Al), zinc (Zn), chromium (Cr), tungsten (W), copper (Cu), silver (Ag), and nickel Ni).

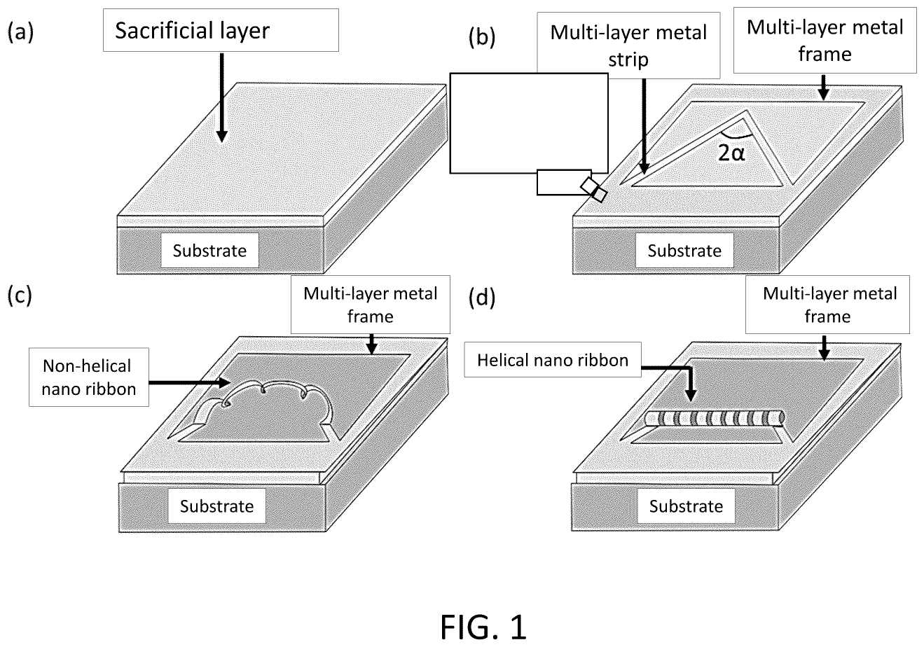

A schematic diagram illustrating a method of forming a helix with tailored, uniform dimensions from an end-tethered NM ribbon is provided in FIG. 1. Initially, a layer of sacrificial material is deposited onto a substrate using, for example, evaporation, as shown in FIG. 1, panel (a). The “sacrificial material” is so called because it will ultimately be selectively removed from the structure, as described below. Optionally, the sacrificial material may itself be patterned into a strip by, for example, applying a blanket coating of the sacrificial material on a substrate and then removing (e.g., etching away) some of the sacrificial material to define the strip. However, the sacrificial material may also be the material at the surface of a bulk substrate.

The selection of the sacrificial material and the material of the electrically conductive strip will be interdependent, as it must be possible to selectively remove (e.g., etch) the sacrificial material from the structure. Examples of suitable sacrificial materials include germanium oxide. Other examples include silicon, germanium, diamond, sapphire, and polymers. Examples of electrically conductive materials that can be used to form stressed electrically conductive strips on these, or other, sacrificial materials include metal layers, such as Au layers, Cr layers, Au/Cr bilayers, Cr/Au/Cr trilayers, copper layers, nickel layers, and silver layers. In multi-layer strips, the sublayers may have the same thickness or different thicknesses. The use of an XeF₂ dry etch to remove a sacrificial material, such as germanium, is advantageous because it does not require a drying step. However, other dry etching, vapor etching, or wet etching methods can also be used.

Next, one or more strips comprising an electrically and thermally conductive material are formed on the sacrificial layer. The strips may comprise multiple layers of different metals (“multi-layer metal strips”). (As used herein, the term metal refers to elemental metals and to metal alloys.) These strips can be formed using known methods, such as photolithography, metal evaporation, and lift-off (FIG. 1, panel (b)). An electrically and thermally conductive strip has a leading end and a trailing end, one or both of which are attached to a substrate. The electrically and thermally conducting strip may be a linear strip having its trailing end firmly attached to a substrate so that the trailing end remains end-tethered to the substrate after the sacrificial material is removed. It is also possible to use a bent conductive strip that is attached to the substrate at both its leading and trailing ends. In this case, both ends of the strip will remain tethered to the substrate even after the sacrificial material is selectively removed, as illustrated in Example. If the strip is a bent strip tethered on both ends, the final electroplated helical conductor will have a right-handed helical segment, a left-handed helical segment, and a connection segment connecting the right-handed helical segment to the left-handed helical segment. In the embodiment show in FIG. 1, panel (b), the strip is V-shaped with a bend angle of 2α and is tethered at both ends to a large-area frame.

The electrically and thermally conductive strips are characterized by a strip length (i.e., the distance between the leading end and the trailing end, a strip width, and a strip thickness. Because the electrically and thermally conductive strip is formed from a thin film, the strip thickness will typically be smaller than the strip width and will typically be less than 0.5 μm. Both the strip thickness and width will be substantially smaller than the strip length. For purposes of illustration only, some embodiments of the electrically and thermally conductive strips have a thickness in the range from about 20 nm to about 300 nm and a width of about 5 μm to about 30 μm. The width of the strip may be, but need not be, uniform along the length of the strip.

The deposited strips are in a stressed state. In multi-layer metal strips, the as-deposited metals in different layers have different stress profiles. As a result, the multi-layer metal heterostructure can be made to have a high residual stress gradient across its thickness. Stress may be imparted to the electrically and thermally conductive strip in a variety of ways. For example, the sacrificial material can be composed of a material that imparts a tensile stress to the strip as the strip is grown thereon. Alternatively, a thermal-expansion mismatch between the sacrificial material and the material of the electrically and thermally conductive strip could provide the requisite stress. In some embodiments of the methods, the stress is engineered into the electrically and thermally conductive strip by tailoring the deposition parameters, such as deposition rate and/or temperature, and/or the film thickness, during its growth. Stress can also be imparted by the thermo-mechanical stress that arises during post-deposition cooling of the deposited material. For example, strips of metals, such as Au and/or Cr, can be formed under intrinsic tensile stress by epitaxial growth, sputtering, or evaporation of the metal onto a sacrificial material. Multi-layer metal strips can include stacks of two, three, or more layers of different metals, wherein the layered strip is deposited in a stressed state caused by a lattice and/or thermal-expansion mismatch between the different metals. By way of illustration, the electrically conductive strip may be a stressed tri-layer comprising a layer of Au between two layers of Cr. In this embodiment, at least one of the two Cr layers should be thin enough to allow for preferential deposition.

The strip is converted into an end-tethered NM ribbon by removing the sacrificial layer using, for example, a selective etch. (Strips that have been released from a sacrificial material are referred to herein as NM ribbons.) The NM ribbons may be formed in a stressed or unstressed state. Depending upon the dimensional and/or strain state of the electrically and thermally conductive strip, the stress that is released may cause the NM ribbon to twist into a non-helical configuration, distorted helical, or helical configuration. These end-tethered NM ribbons can reconfigure into different shapes and dimensions under an applied load. In the example shown in FIG. 1, panel (c), the NM ribbon bends out of plane and twists in plane to form a non-helical ribbon. A non-helical ribbon may have an irregularly twisted shape, may only be bent out of plane, or may show a certain degree of helicity but with non-uniform diameter and pitch between the two tethers.

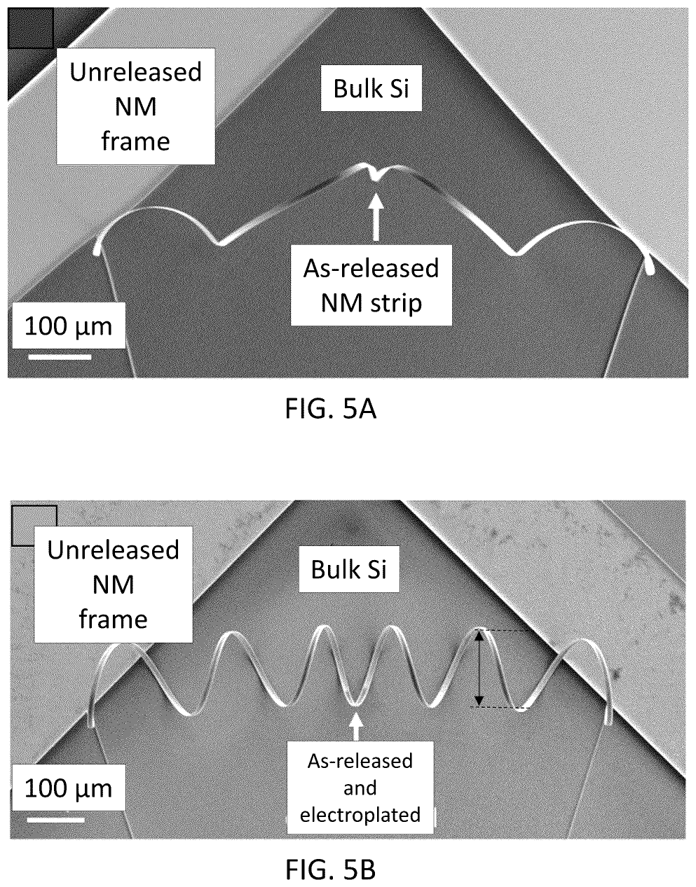

If the starting NM ribbon has a non-helical configuration, it may be planar or may have twists or bends along its length that render it non-planar, yet not uniformly helical. If the starting NM ribbon is a helix, the helix may initially have a substantially uniform pitch and uniformly shaped loops, or may be distorted with a non-uniform pitch and/or non-uniform coils. For the purposes of this application, a helical configuration, or helix, refers to a configuration in which the turns in a NM ribbon form a series of three or more contiguous loops around an axis running along a length dimension. The loops in a helix are characterized by crests and the distance between the crests of the neighboring loops determines the pitch of the helix. The diameter of a helix is measured as the distance between the crests and troughs of the loops in the NM ribbon helix, where the helix diameter measurements are made using the inner surfaces of the NM ribbon helix. (This is illustrated by the double arrow in FIG. 5B.) For a helix in which the loops are not perfectly uniform, the helix diameter can be calculated as an average diameter over the length of the helix, based on the crest and trough of each full loop.

In a distorted helix, there is a wide variation in the pitches along the helix. For example, in a distorted helix the difference between the largest pitch and the shortest pitch may be a factor of two or greater. In contrast, in a uniform helical conductor, the pitch and dimensions of the loops along the helix are highly regular along the helix. By way of illustration, uniform helical conductors having variations in helix pitch and diameter of less than 10% along the length of the helix, including helical conductors having variations in helix pitch and diameter of less than 5% along the length of the helix, and further including helical conductors having variations in helix pitch and diameter of less than 2% along the length of the helix can be formed using the methods described herein.

A thin metal film is then preferentially electrodeposited on one side the end-tethered NM ribbon to induce helix self-assembly or helix dimension control. Preferential deposition means that the metal film is electrodeposited only on one surface of the NM ribbon, but not on the opposing surface, or the electrodeposited metal film forms a thicker film on one surface of the NM ribbon than on the opposing surface. The preferential electrodeposition on one surface produces a stress gradient, which induces self-assembly or dimension control. Preferential electrodeposition can be accomplished by, for example, electroplating a metal onto a multi-layer NM ribbon having one surface that is formed from an electroplatable material and an opposing surface that is made from a different material that is not electroplatable or that is less readily electroplated. By way of illustration only, a Cr/Au bilayer NM ribbon can be used, where the Au layer is electroplated with an Au film during the electroplating step, while the Cr layer remains un-plated or is electroplated to a lesser extent. By way of further illustration, an electroplatable metal layer, such as an Au layer, can be sandwiched between two layers of a material that is not readily electroplated, wherein one of the two sandwiching layers is porous or discontinuous. Porosity of a sandwiching layer may be achieved by making the layer thin and, in particular, thinner than the other sandwiching layer and/or by tailoring the deposition conditions of the layer to achieve a high density of pinholes. A material with a high density of pinholes can be formed, for example, via evaporative deposition at a high rate at or near room temperature. In this embodiment, a metal film (e.g., an Au film) can be electrodeposited on the middle layer (e.g., the Au layer) and can grow up through and over the porous or discontinuous layer. The electroplating may change (increase or decrease) the helix inner diameter and/or change the loop pitch and/or improve the uniformity of the loop pitch and diameter. For clarity, it is noted that the changes in helix pitch and diameter described herein refer to changes in pitch and diameter of the NM ribbon helix and not just to reductions in pitch and diameter caused by the increased overall thickness of the helical conductors due to the addition of the metal plating.

In preferential electroplating, a metal film is preferentially plated onto at least one exposed surface of an electroplatable layer in the NM ribbon, which serves as seed layer for the plating layer. As the plating metal is electrodeposited with a given residual stress on the end-tethered NM ribbon, new equilibrium shapes can be achieved. Thus, the electroplating can convert an end-tethered NM ribbon into a helix—if it has a non-helical configuration—or can change an end-tethered NM ribbon's inner diameter and pitch and/or render its inner diameter and pitch more uniform, if it has a helical configuration. In the example of FIG. 1, panel (d), upon preferential electrodeposition of a metal film onto one side of the non-helical NM ribbon, it is converted into a helical NM ribbon (i.e., a helical conductor) characterized by helix loops having a uniform pitch and uniform diameters. It is not necessary for all of the layers in a multi-layer strip to be electroplatable. The NM ribbons can be electroplated with a metal that is the same as, or different from, metal(s) used to form the electrically and thermally conductive strip. Electroplating may be carried out by immersing the NM ribbon in an electroplating solution, with optional heating specific to a solution, and creating a voltage difference between an electroplating electrode and a counter electrode to induce metal ions in the electroplating solution to deposit onto the surface of the NM ribbon.

By way of illustration, electroplating a NM ribbon with a layer of metal, such as Au, wherein the metal layer has a thickness in the range from 0.2 μm to 20 μm, including thicknesses in the range from 1 μm to 5 μm, can be carried out using a pulsed alternating current with a frequency in the range from 0.1 Hz to 1 MHz, including frequencies in the range from 0.1 to 10 Hz, can induce helix self-assembly or can alter the inner diameter and pitch of a previously formed helical NM ribbon. However, the electroplating can also be carried out using a direct current. A suitable current density during electrodeposition is about 2 mA/cm², a suitable electroplating solution temperature is in the range from 50° C. to 100° C., and a suitable electrodeposition pH is in the range from 6 to 7. However, these electroplating parameters are provided for guidance only and other electroplating parameters can be used.

The methods can be used to form helical conductors with a range of scalable loop pitches and diameters. For example, helical conductors having loop pitches and/or diameters in the range from 40 μm to 1000 μm, including the range from 50 μm to 700 μm, and further including in the range from 80 μm to 200 μm. Helical conductors with lengths of up to 5 mm, or longer can be fabricated. The electroplated helices can be fabricated with inner loop diameter to loop pitch ratios in a range of, for example, 0.2 to 2. Electroplated helices having dimensions in these ranges may be used as SWSs in mm-wave and THz TWTAs. However, electroplated helical conductors with dimensions outside of these ranges can also be made. Electroplated helices are also useful as helical antennas, metamaterials unit cells, and on-chip transformers bridging radio- and mm-waves frequencies.

More information about methods by which NM ribbons can be fabricated by the release of a stressed, end-tethered strip of electrically and thermally conducting material from an underlying sacrificial material are described in the Examples below and in U.S. patent application publication 2021/0367573, the entire disclosure of which is incorporated herein by references. It should be noted, however, that while U.S. patent application publication 2021/0367573 teaches the formation of helices that form upon the release of a stressed conducting strip from a sacrificial material, it is also possible to form non-helical NM ribbons using the same methods, by adjusting the dimensions and stress state of the starting strip.

Without intending to be bound to any particular theory of the invention, the inventors believe that the electrodeposited metal film alters the stiffness of the NM ribbon, while also imparting enough mechanical stress to drive the assembly of the NM ribbon into a helix with a uniform diameter and pitch along its axis. The equilibrium diameter of a helix that is self-assembled via electroplating is defined by the balance between the bending moment generated by relaxation of residual stress in the NM ribbon as metal deposition occurs and the NM ribbon's resistance to bending (or bending stiffness). The magnitude of the strain gradient across the thickness of the deposited metal film determines the strength of the bending moment. The strain gradient is highly tunable across the thickness of the NM ribbons (h), leading to a variety of possible strain profiles and strain gradients as deposition progresses and h increases. For example, different strain gradient vs. thickness trends can be obtained by varying electrodeposition parameters during the process or electrodepositing a stack of metals that are expected to have different residual strains. The resistance to bending of the NM ribbon increases with thickness (h) as E×h³ where E is the elastic modulus of the metal. Based on this model, electrodeposition on end-tethered NM ribbons can generate self-assembled helices with a highly tunable diameter, whether the NM ribbons are initially in a non-helical, and even planar, configuration or have a helical configuration with dimensions or uniformity that renders the helix unsuitable for a desired application.

Whether the electroplated metal increases or decreases the inner diameter and pitch of a starting helix will depend on the stress profile across the thickness of the NM ribbon and the bending stiffness of the NM ribbon. At lower thicknesses, the bending moment dominates, resulting in a decrease in the inner loop diameter and pitch of the helix, while at greater thicknesses, the bending stiffness dominates, resulting in an increase in the inner diameter and pitch of the helix. In some embodiments of the methods, electroplating changes (increases or decreases) the average helix loop diameter and/or pitch of a starting helix by at least 20%, at least 30%, at least 50%, or at least 100%.

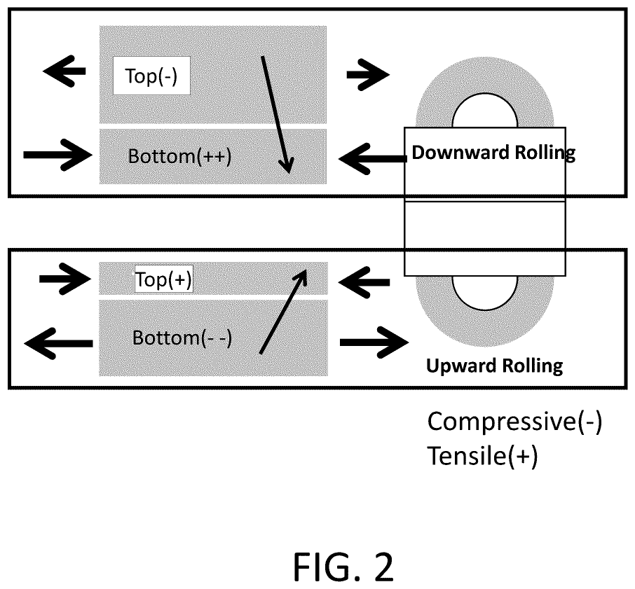

FIG. 2 schematically illustrates the effect of the metal layer thickness on the rolling behavior of a NM ribbon. A + sign is used to indicate tensile stress and − sign is used to indicate compressive stress; double use of either sign indicates a greater amount of stress of one type in comparison to stress of the other type. First, considering a simple example of a bilayer NM ribbon, as shown in FIG. 2, the top layer may be under compressive stress (−) while the bottom one has tensile stress (FIG. 2, upper panel). The magnitude of the stress in the bottom layer is larger than the magnitude of the stress in the top layer, as indicated by the (++) sign in the bottom layer. The stress gradient is from the top layer to the bottom layer and the only possible way to release the built-up stress is by downward rolling, until both layers in the bilayer attain their equilibrium. In contrast, FIG. 2, lower panel, illustrates the case when the top layer is under tensile stress (+) and bottom layer has compressive stress (−−). The bilayer releases the residual stress by upward rolling, as shown in the figure. The example shows that stress gradients plays a prominent role in determining the bending moment acting on a NM ribbon, which effectively drives the formation of the NM ribbon into a helix and defines the diameter of the helix for a given stiffness of the NM ribbon.

A second aspect of the invention provides methods for making a helical conductor from a non-helical conductor using uniform electrodeposition of a metal layer onto the non-helical conductor. In these methods, a non-helical conductor can be made using the methods described above and shown schematically in FIG. 1, except that the starting non-helical conductor can be a single layer NM ribbon, since preferential deposition on one side of the NM ribbon is not needed. By way of illustration, the NM ribbon may be formed from a strip of a single layer of an electroplatable metal, such as Au, Al, Zn, Cr, W, Cu, Ag, or Ni. The dimensions of the strip and the NM ribbon made therefrom, may be as described above. In the case of helix self-assembly induced by uniform, rather than preferential, metal electrodeposition, the electrodeposited metal produces enough of a stress gradient in the NM ribbon to induce assembly even if metal films of identical thickness are electrodeposited the opposing surfaces of the NM ribbons.

In addition to inducing helix formation or tailoring helix dimensions, electroplating increases the thickness of the resulting helix, which may provide better heat transfer and lower signal loss for a TWTA and also allows for further tailoring of the signal propagating properties (e.g., operating frequencies) of an SWS, whereby smaller inner-diameter wave tubes amplify higher-frequency signals.

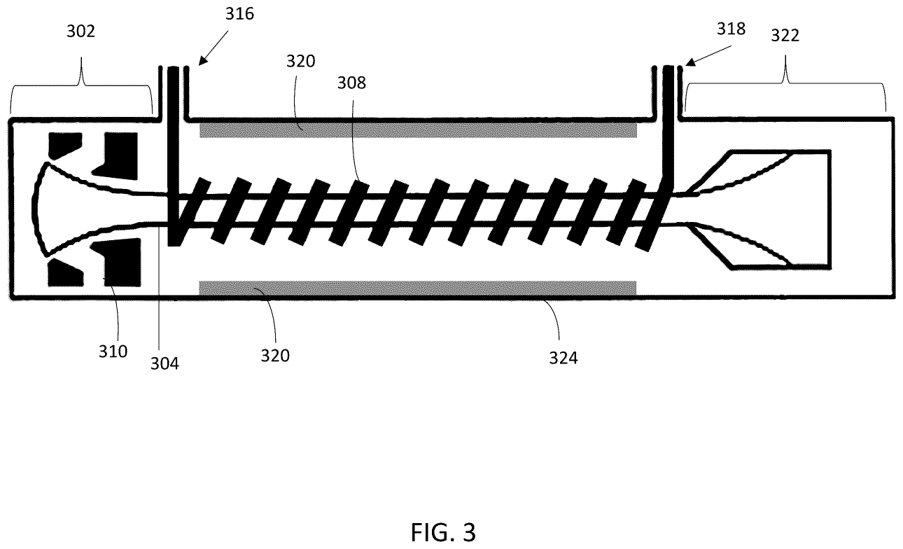

The basic components of one embodiment of a TWTA are shown in FIG. 3. The components include an electron gun 302, positioned to direct an electron beam 304 along an axis 306 through an SWS comprising an electrically conductive helix 308 that spirals around axis 306. Electron gun 302 is composed of a control anode 310, a control grid 312, and a cathode 314. The TWTA further includes a signal input coupler 316 that introduces an EM signal into helix 308 and a signal output coupler 318 that receives the amplified EM signal from helix 308. Steering magnets 320 or electric fields are arranged around helix 308 to focus and steer electron beam 304, and an electron collector 322 is positioned along axis 306, opposite electron gun 302, to remove the unused electron beam energy. Helix 308 is housed in a vacuum housing 324. An attenuator (not shown) may also be provided along the path of the electron beam to isolate the input and output.

When electron beam 304 is emitted from electron gun 302 and accelerated toward electron collector 322, the electrons are in close proximity to the propagating EM wave. The electron beam is directed along the axis of the helix either through the center of the helix or outside of the helix. In some embodiments, multiple electron beams (“beamlets”) are used. These beamlets are directed in a circular pattern around the periphery of the helix. The conductive helix slows the axial phase velocity of the EM wave to, or below, the speed of the electrons in the beam. The kinetic energy in the electron beam is coupled into the EM wave, thereby amplifying the EM wave.

### EXAMPLES

These examples illustrate a process for inducing helix self-assembly or helix dimension control on a stressed NM ribbon and provide guidance for the selection of processing parameters for plating a uniform metal film.

### Fabrication of Cr Au Cr Helices

Cr/Au/Cr helices were formed using the process shown in FIG. 1. The helices were formed from Cr (5 nm)/Au (300 nm)/Cr (30 nm) strips with widths in the range from 5 μm to 10 μm on sacrificial Ge layers over a bulk (100) silicon (Si) substrate. The Ge was deposited to a thickness of 50 nm at 1 Å/s using e-beam deposition at ˜1.0×10⁻⁶ Torr pressure. The inverted V shape patterning using photolithography was performed as mentioned in the Divya J. Prakash, Matthew M. Dwyer, Marcos Martinez Argudo, Mengistie L. Debasu, Hassan Dibaji, Max G. Lagally, Daniel W. van der Weide, and Francesca Cavallo, ACS Nano 2021 15 (1), 1229-1239.

The tri-layer strips of metal consisting of Cr/Au/Cr were deposited using e-beam evaporation at ˜1.0×10⁻⁶ Torr pressure. The first 5 nm-thick Cr layer was deposited at 1 A/s. The Au layer was deposited at 0.2 Å/s to a thickness of 300 nm. The second 30 nm-thick Cr layer was deposited at 1 Å/s. Lift off was performed in acetone at 25° C.

To obtain self-assembled end-tethered helices, the Ge was selectively etched using an SPTS Xactix E1 etcher with 4-10 continuous cycles of 10 s to 15 s at 2.9 T XeF₂ pressure. The released NM ribbons were used for the electroplating experiments without any further treatment.

### Helix Characterization

The helices were characterized using a Zeiss Gemini 450 FESEM (Field Emission Scanning Electron Microscope) with a 10 KeV electron gun voltage at 66 pA current and an SE2 electron detector at 110 V. Cross-sectional images of the helical NM ribbons were measured at nearly 82° tilt angle by field-emission (FESEM).

A Bruker Dimension Icon AFM was used for measuring the surface roughness of helices.

### Au Electroplating Procedure

Fresh Elevate® gold 7990 NBV solution RTU (8.2 g/l) from Technic was used for Au electroplating in this study. A Keithley 2400 source meter with platinized mesh was used as the anode and the helices were used as the cathode in 100 mL of the elevate® gold 7990 NBV plating solution. A peak current density (iₚ) of 2 mA/cm² was used and the temperature of the electroplating was kept at approximately 60° C. according to the data specification sheet of the electrolyte solution. A uniform temperature distribution inside the solution was achieved by keeping the solution in a beaker on a hot plate at a particular temperature for 20 minutes with the stirrer ON. Furthermore, due to the helical structure of the samples, stirring was turned OFF before the start of any experiment. The pH of the solution was ˜6.2.

### Preferential Electroplating

Preferential electroplating on Cr/Au/Cr NM ribbons fabricated using the methods described above was demonstrated by electroplating Au onto the NM ribbons in a pulsed current mode using a train of rectangular pulses in regular cycles. In each cycle, a current source delivered a DC output for a specific on time (tₒₙ) and blocked it for the rest of the duration (during the off time or t_{off}). The duty cycle and the frequency of the pulsed current are D=(tₒₙ*100)/(tₒₙ+t_{off})¹⁻³ and f=1/(tₒₙ+t_{off}), respectively.

Pulsed electroplating at very- and ultra-low frequency (VLF and ULF) or electroplating with f<10 Hz was used as it is expected to produce coatings with a fine-grained surface structure, a uniform thickness, and a low roughness. Suitable electroplating parameter include, but are not limited to, 0.1 Hz≤f≤10 Hz, 0.01 s≤tₒₙ≤1 s, 0.09 s≤t_{off}≤19 s, a current density Jₚ=2 mA/cm², duty cycle, D=5-10% and a solution temperature of 58.5° C.

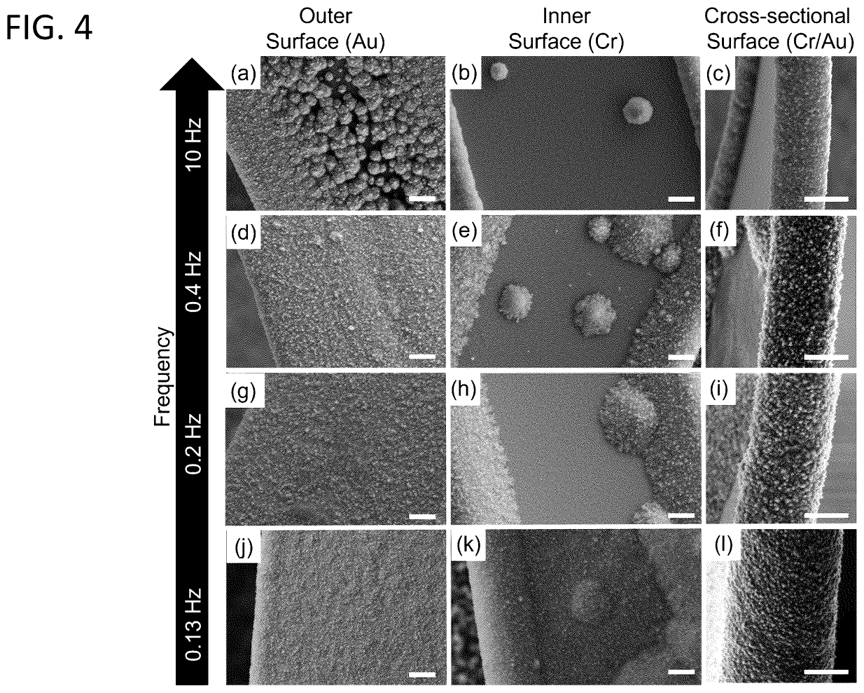

FIG. 4 displays scanning electron micrographs (SEMs) of representative helical NM ribbons' outer (panels (a), (d), (g), and (j)), inner (panels (b), (e), (h), and (k)), and cross-sectional (panels (c), (f), (i), and (l)) surfaces after pulse plating using different frequencies. The SEMs show that electrodeposition occurred preferentially at the cross-sectional and outer surfaces of the helices. The outer surfaces of the helices are either Au surfaces or porous Cr surfaces through which the underlying Au has been exposed due to the complete or partial removal of the thinner Cr layer during the XeF₂ etch, as described below. The SEMs further show that the maximum thickness of the electroplated Au increased at decreasing frequency.

To determine why preferential electrodeposition at the cross-sectional and outer surfaces of the NM ribbons occurred, the NM ribbons were studied by energy-dispersive x-ray spectroscopy (EDS) upon their release by XeF₂ etching of the Ge sacrificial layer. It was observed that the 5 nm Cr layer was removed from the layered structure. During electroplating, the top, the bottom, and the cross-sectional surfaces of the ribbon are exposed to the electroplating electrolyte solution. The Cr and the Au layers are both negatively charged by an electrical current. However, the Au has a higher electronegativity than Cr leading to electrons transferring from Cr to Au. A higher concentration of electrons in the Au layer results in a larger number of metal ions being attracted to the Au surface and reduced to metallic form on Au than on Cr in a given time. Therefore, the Au is deposited at a higher rate on the exposed Au on the edge and the outer surfaces of the NM ribbon helix. For ribbons released during shorter XeF₂ etching, the 5 nm Cr is not entirely removed, and non-uniform electrodeposition of Au occurs on both the outer and the inner surface of the end-tethered ribbon.

### Conversion of Non-Helical NM Ribbon Into a Helical NM Ribbon

Au electroplating was used to induce helix formation from a pre-formed stressed, non-helical NM ribbon made according to the methods described above. Electroplating conditions used to plate the NM ribbon of FIG. 5A were a current density of 2 mA/cm², T=58±3° C., tₒₙ=250 ms, f=0.2 Hz, D=0.1, and t_{dep}=660 s. The total thickness of the NM ribbon after electroplating was ˜1.2 μm and the diameter to pitch ratio was ˜1 in the final electroplated helix (FIG. 5B).

After electroplating, the non-helical NM ribbon self-assembled in a helix with uniform diameter and pitch, as shown in FIG. 5B. The average measured diameter and pitch along the axis of a representative helix made according to this method were 134±2 μm and 133±15 μm, respectively. SEM images of the helical NM ribbons showed preferential deposition characteristics consistent with those shown in FIG. 4. The maximum electroplated Au layer thickness was estimated to be 0.76 μm from high-magnification SEM images of the cross-sectional surfaces of the helical NM ribbons.

### Altering the Dimensions of a Helical NM Ribbon

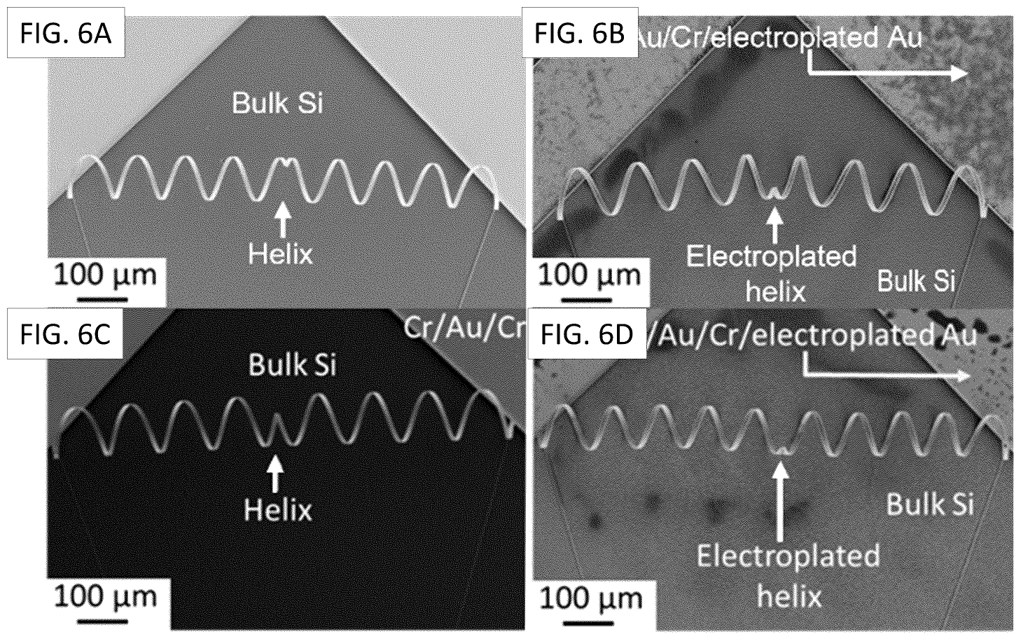

Au electroplating was also used to tailor the diameter and pitch of helical NM ribbons. The initial helical NM ribbons (e.g., FIGS. 6A and 6C) were formed from Cr (5 nm)/Au (300 nm)/Cr (30 nm) strips on sacrificial Ge layers over a silicon (Si) wafer substrate, as described in the methods section.

Two sets of electroplating conditions were used to plate the helical NM ribbons. The first set of electroplating conditions were a current density of 2 mA/cm² for 420 s, tₒₙ=0.01 s, and T=58±3° C. to produce a total helix thickness (NM ribbon thickness plus Au plating layer thickness) of ˜5.2 μm. The second set of electroplating conditions were a pulsed current density of 2 mA/cm², tₒₙ=0.01 s, T=58±3° C. for 660 s with total helix thickness of ˜1.1. The total thickness of the NM ribbon after electroplating was ˜1.2 μm and the diameter to pitch ratio was ˜1 in the final electroplated helix (FIG. 6B).

Characteristics of helical ribbon at various levels for tailoring its dimensions. (a, d) helical ribbon before electrodeposition and (b,c,e,f) helical ribbon after electrodeposition. (b) Increase in diameter of the helical ribbon shown in (a) after electroplating using conditions: current density of 2 mA/cm² for 420 s, tₒₙ=0.01 s, and T=58±3° C. with total helix thickness of ˜5.2 um as shown in cross-sectional image of the electroplated helix in (c). (e) Decrease in diameter of the helical ribbon after electroplating of helix shown in (d) after electroplating using conditions: pulsed current density of 2 mA/cm², tₒₙ=0.01 s, T=58±3° C. for 660 s with total helix thickness of ˜1.1 um as shown in cross-sectional image of the electroplated helix in (f).

FIG. 6A shows a helical NM ribbon with an average diameter of 92 μm. After electroplating a Au film with a 1.8 μm maximum thickness onto the NM ribbon, the helix diameter of the helical NM ribbon increased to 102 μm (FIG. 6B). In contrast, the helix diameter of the helical NM ribbon FIG. 6C, reconfigured to a structure of smaller diameter after electroplating a 0.8 μm Au film onto its surface (FIG. 6D). Specifically, the helix diameter and helix pitch of the helical NM ribbons were reduced from 97±2 μm and 99±2 μm to 81±2 μm and 80±2 μm, respectively (FIG. 6C-6D).

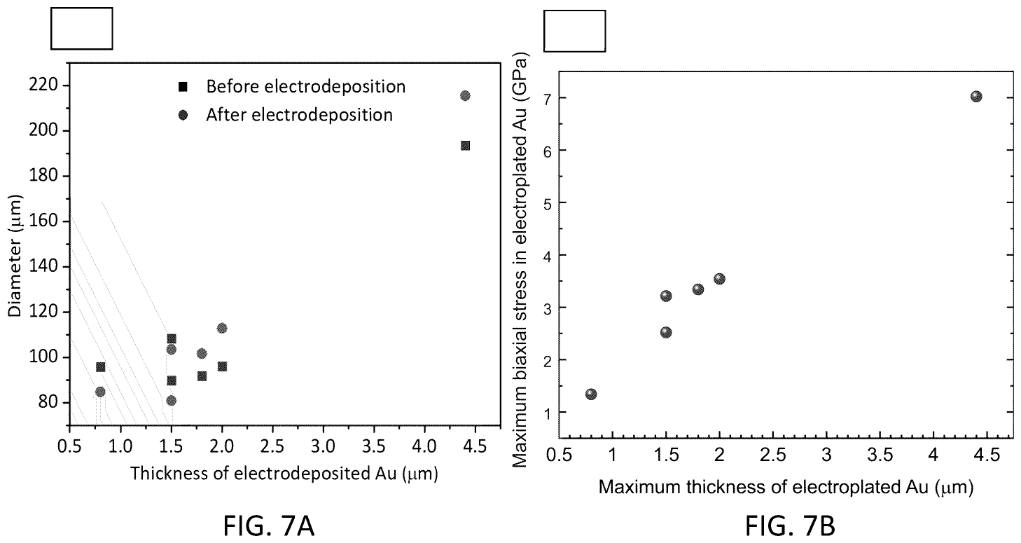

Au was electroplated onto helical NM ribbons with different initial helix diameters and using different deposition parameters to obtain helix thicknesses in the range of 0.8 to 5 μm. FIG. 7A shows a summary of the average helix diameter for different helical NM ribbons before and after the electroplating. Two thickness regimes were identified corresponding to the helix diameter increasing or decreasing, depending upon the maximum thickness of the electroplated Au layer, as measured by SEM. The average tensile stress, in GPa, for the electroplated Au layer after electroplating the NM ribbons under the above-mentioned electroplating conditions was also calculated (FIG. 7B). As a multilayered structure was used, a mechanical model with plane stress and generalized plane strain conditions at equilibrium was used to calculate the average stress in the electroplated Au. This model takes into account the stress gradient among all the layers.

When the thickness of the electroplated Au was less than a certain thickness (approximately 1.6 μm in this example), the effect of increasing stress (a driving force for decreasing diameter) dominates over the effect of increasing thickness (a driving force for increasing diameter), increasing the stress gradient and driving the helix to reduce its diameter. With a further increase in the thickness of electroplated Au (greater than approximately 1.7 μm in this example), the effect of increasing stress fades away and the effect of increasing thickness dominates, reducing the stress gradient and expanding the helix to a larger diameter.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean only one or can mean “one or more.” Embodiments of the inventions consistent with either construction are covered.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

1. A method of making a helical conductor, the method comprising:
forming an end-tethered nanomembrane ribbon having a first surface, a second surface opposite the first surface, and a thickness of less than 1000 nm, wherein the end-tethered nanomembrane ribbon has a non-helical configuration or is a starting helix having a helix diameter and helix pitch; and
converting the end-tethered nanomembrane ribbon into a final helix by electroplating a metal film having a thickness in the range from 0.2 μm to 10 μm preferentially on the first surface, wherein the electroplating induces the self-assembly of the nanomembrane ribbon having the non-helical configuration into the final helix or induces a change in the helix diameter, helix pitch, or both of the starting helix to form the final helix.

2. The method of claim 1, wherein the electroplating is conducted using a pulsed current.

3. The method of claim 2, wherein the pulsed current has a frequency in the range from 0.1 Hz to 10 Hz.

4. The method of claim 1, wherein the metal film is a gold film.

5. The method of claim 4, wherein the first surface is a gold surface and the second surface comprises a material that is more resistant to gold electroplating than gold.

6. The method of claim 5, wherein the material that is more resistant to gold electroplating is chromium.

7. The method of claim 6, wherein the nanomembrane ribbon comprises a gold layer sandwiched between a porous or discontinuous chromium layer that provides the first surface and a non-porous, continuous chromium layer that provides the second surface.

8. The method of claim 1, wherein the nanomembrane ribbon comprises a layer of an electroplatable material sandwiched between a porous or discontinuous layer of a non-electroplatable material that provides the first surface and a non-porous, continuous layer of a non-electroplatable material that provides the second surface.

9. The method of claim 1, wherein the nanomembrane ribbon has the non-helical configuration.

10. The method of claim 1, wherein the nanomembrane ribbon is the starting helix and the electroplating decreases the diameter and pitch of the starting helix.

11. The method of claim 1, wherein the nanomembrane ribbon is the starting helix and the electroplating increases the diameter and pitch of the starting helix.

12. The method of claim 1, wherein the end-tethered nanomembrane ribbon has a first end, a second end opposite the first end, and a bend along its length and further wherein the first end and the second end are tethered to a substrate.

13. The method of claim 1, wherein the final helix has a diameter in the range from 40 μm to 1000 μm.

14. The method of claim 1, wherein the final helix has a pitch in the range from 40 μm to 1000 μm.

15. The method of claim 1, wherein the final helix has a diameter in the range from 40 μm to 200 μm and a pitch in the range from 40 μm to 200 μm.

16. The method of claim 6, wherein the final helix has a diameter in the range from 40 μm to 1000 μm.

17. The method of claim 6, wherein the final helix has a pitch in the range from 40 μm to 1000 μm.

18. The method of claim 6, wherein the final helix has a diameter in the range from 40 μm to 200 μm and a pitch in the range from 40 μm to 200 μm.

19. A method of making a helical conductor, the method comprising:
forming an end-tethered nanomembrane ribbon having a first surface, a second surface opposite the first surface, and a thickness of less than 1000 nm, wherein the end-tethered nanomembrane ribbon has a non-helical configuration; and
converting the end-tethered nanomembrane ribbon into a helix by electroplating a metal film having a thickness in the range from 0.2 μm to 10 μm onto the end-tethered nanomembrane ribbon, wherein the electroplating induces the self-assembly of the nanomembrane ribbon having the non-helical configuration into a helix.

20. The method of claim 19, wherein the end-tethered nanomembrane ribbon is formed from a single layer metal strip.

21. The method of claim 20, wherein the single layer metal strip is a gold strip.

22. The method of claim 21, wherein the metal film is a gold film.

23. The method of claim 19, wherein the end-tethered nanomembrane ribbon has a first end, a second end opposite the first end, and a bend along its length and further wherein the first end and the second end are tethered to a substrate.

24. The method of claim 19, wherein the helix has a diameter in the range from 40 μm to 1000 μm.
